(19) United States
(12) Patent Application Publication
(10) Pub. No.: US 2005/0140994 A1
(43) Pub. Date: Jun. 30, 2005

(54) Image processing apparatus, image processing method and image processing program

(75) Inventor: Noriko Hasegawa, Ebina-shi (JP)

Correspondence Address: OLIFF & BERRIDGE, PLC, P.O. BOX 19928, ALEXANDRIA, VA, 22320, US

(73) Assignee: FUJI XEROX CO., LTD., Minato-ku (JP)

(21) Appl. No.: 10/996,475

(22) Filed: Nov. 26, 2004

(30) Foreign Application Priority Data
Dec. 25, 2003 (JP) 2003-429667

(51) Int. Cl. G06F 15/00; G03F 3/08

(52) U.S. Cl. 358/1.9; 358/518; 382/167

(57) ABSTRACT

An image processing apparatus for color converting an input image signal to an output image signal includes a multidimensional look-up table and a judgment unit. The multidimensional look-up table correlates a signal value of the output image signal corresponding to a signal value of the input image signal with a position on a coordinate axis in a predetermined color space and holds it, secures a holding area for holding a specific color signal value in an area on the coordinate axis, the area is not taken by the signal value of the input image signal. The judgment unit judges whether the signal value of the input image signal is a specific color or not. When the input image signal is the specific color, address conversion is performed on the input image signal, and the specific color signal value in the holding area is acquired based on the multidimensional look-up table.

### BACKGROUND OF THE INVENTION

1. Field of the Invention

The present invention relates to an image processing apparatus, an image processing method and an image processing program, which are used in a computer having an image processing function, a digital copying machine, or the like, and perform a color conversion processing on an image signal for expressing a color image.

2. Description of the Related Art

In general, as an apparatus for outputting a color image, although a display apparatus such as a CRT (Cathode Ray Tube) and a printing apparatus such as a printer are in wide spread use, it is known that there is a difference in reproducible color range since these are different from each other in output systems. Thus, for example, like a case where an image formed on a CRT is printed by a printer, when the output of the same image data is made by different output apparatuses, there is a possibility that a color arises which can not be reproduced. From this, when a color image is handled through plural apparatuses, it becomes necessary to perform a so-called color conversion processing in which a given color image signal is replaced by a color image signal in the color reproducible range of an output apparatus.

In general, the color conversion processing is often performed using a multidimensional look-up table and an interpolation (see, JP-A-2000-232588). The multidimensional look-up table holds, at addresses corresponding to respective lattice points, signal values in a color space at an output side after conversion of signal values at the respective lattice points of a space obtained by dividing a color space at an input side. That is, since the multidimensional look-up table correlates a signal value of an output image signal corresponding to a signal value of an input image signal with a position on a coordinate axis in a predetermined color space and holds it, when the address input as to the input image signal is made to the multidimensional look-up table as stated above, the signal value of the output image signal held at the address is outputted. However, in the case where the output image signal is outputted as a color image by an electrophotographic system, from the viewpoint of improvement in output picture quality, reduction in toner consumption and the like, with respect to an achromatic color, there is a case where it is desirable to perform image formation by using only a toner of K (black) color, not overlapping toners of respective colors of YMC or YMCK. From this, it is proposed that at the color conversion processing, when a signal value of an input image signal is one concerning the achromatic color, a signal value of only K in a color space is outputted as a signal value of an output image signal corresponding to the signal value of the input image signal concerning the achromatic color.

In general, in the multidimensional look-up table, since there is a limitation in a storage area which can be secured therefor, as described above, the signal values are held at the respective lattice points of the space obtained by dividing the color space. A signal value other than those at the lattice points is obtained by interpolation from the signal values of the lattice points. Thus, when the multidimensional look-up table is constructed, when a signal value of only K is held in an address area corresponding to a signal value of an input image signal concerning the achromatic color, in the case where the signal value other than those at the lattice points is obtained by the interpolation, there can occur such a case that the interpolation is performed on the basis of the signal value of only K and the signal value of YMC or YMCK. Accordingly, with respect to the signal value obtained by the interpolation, there is a fear that the reproduction of color becomes unnatural, and as a result, it is conceivable that deterioration is caused in the picture quality of a color image after the color conversion processing.

### SUMMARY OF THE INVENTION

The present invention has been made in view of the above circumstances and provides an image processing apparatus, an image processing method and an image processing program, which can output a signal value of an output image signal excellently reproduced in both a case where a signal value of an input image signal indicates a specific color typified by an achromatic color and a case where the signal value indicates a color near the specific color, and can realize the output of a high quality color image.

According to an embodiment of the present invention, the image processing apparatus for color converting an input image signal to an output image signal includes a multidimensional look-up table which correlates a signal value of the output image signal corresponding to a signal value of the input image signal with a position on a coordinate axis in a predetermined color space and holds it, secures a holding area in an area on the coordinate axis which the signal value of the input image signal can not take and holds a specific color signal value, and a judgment unit which judges whether or not, with respect to an input image signal as an object of color conversion, a signal value of the input image signal is one concerning a specific color, wherein as a result of judgment of the judgment unit, when the input image signal as the object of the color conversion is the one concerning the specific color, address conversion is performed on the input image signal, and the specific color signal value in the holding area is outputted from the multidimensional look-up table.

### BRIEF DESCRIPTION OF THE DRAWINGS

Embodiments of the present invention will be described in detail based on the following figures, wherein:

FIG. 1 is a block diagram showing a schematic structural example of an image processing apparatus of the invention;

FIGS. 2A and 2B are explanatory views showing an example of a signal holding area in a CLUT; and

FIG. 3 is a flowchart showing an example of a processing procedure in an image processing method of the invention.

### DETAILED DESCRIPTION OF THE INVENTION

Hereinafter, an image processing apparatus, an image processing method and an image processing program according to the present invention will be described with reference to the drawings.

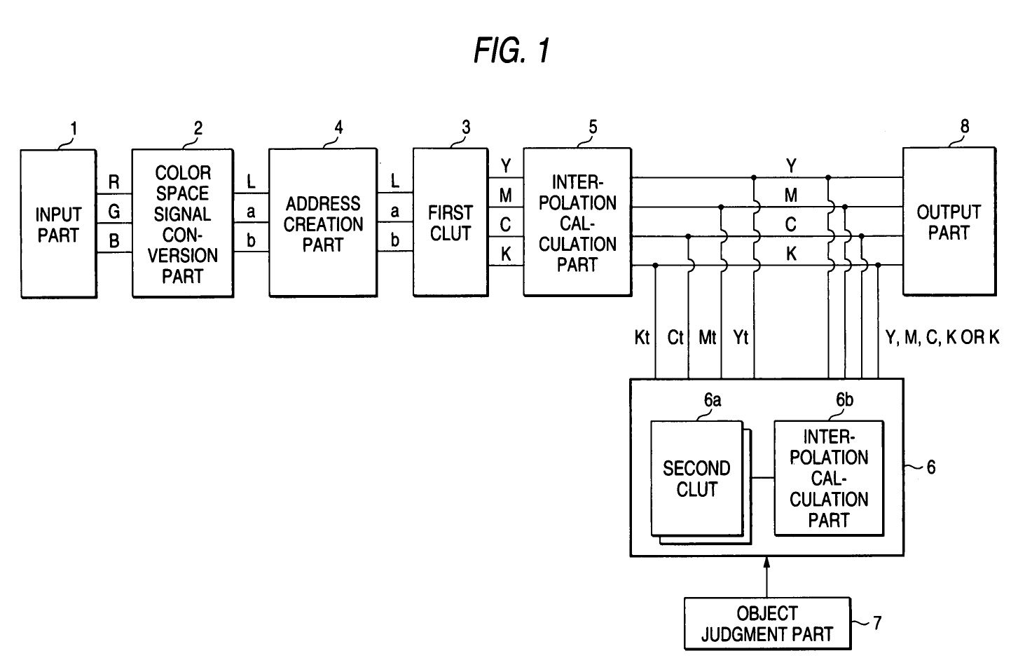

First, a schematic structure of an image processing apparatus will be described. FIG. 1 is a block diagram showing a schematic structural example of the image processing apparatus of the invention. The image processing apparatus described here is mounted in an image output apparatus such as a digital copying machine or a printer, is mounted in a server apparatus connected to the image output apparatus, or is mounted in a computer (driver apparatus) giving operation instructions to the image output apparatus and is used. As shown in the example of the drawing, the image processing apparatus includes an input part 1, a color space signal conversion part 2, a first color look-up table (hereinafter abbreviated to “CLUT”) 3, an address creation part 4, an interpolation calculation part 5, an achromatic color conversion part 6, an object judgment part 7, an output part 8, and a not-shown user interface (hereinafter abbreviated to “UI”).

The input part 1 is for acquiring an input image signal. As the input image signal, for example, a color image signal in an RGB color space for displaying on a CRT or the like can be mentioned.

The color space signal conversion part 2 is for performing a color space conversion processing into a color space used at a latter stage in a case where a color space of an input image signal is different from the color space used at the latter stage. For example, in the case where the input image signal is the signal of the RGB color space, and the processing at the latter stage is performed in the color space independent on the apparatus, for example, a CIE-L*a*b* color space, the color space signal conversion part 2 performs the conversion from the RGB color space to the L*a*b* color space. However, in the case where the input image signal is the signal of the color space independent on the apparatus, this function is unnecessary.

Further, the color space signal conversion part 2 judges whether or not, with respect to the input image signal as an object of the conversion, the signal value of the input image signal is one concerning an achromatic color. Here, “one concerning an achromatic color” includes, for example, an achromatic color and one with a color value in which a distance from an achromatic color axis (for example, an L* axis in the CIE-L*a*b* color space, and this axis will be here in after referred to as a “gray axis”) is a predetermined threshold or less. Accordingly, in the color space signal conversion part 2, on the basis of the comparison between the signal value of the input image signal and the predetermined threshold, it is judged whether or not the signal value is one concerning the achromatic color.

The first CLUT 3 has a function as a multidimensional look-up table used for color conversion of the input image signal to the output image signal. That is, in the first CLUT 3, the signal value of the output image signal corresponding to the signal value of the input image signal is correlated with a position on a coordinate axis in a predetermined color space (for example, the CIE-L*a*b* color space) and is held. Further, not only the corresponding relation between the input image signal and the output image signal is held, but also a holding area is secured in an area on the coordinate axis which the signal value of the input image signal cannot take, and a specific color signal value is held in the holding area.

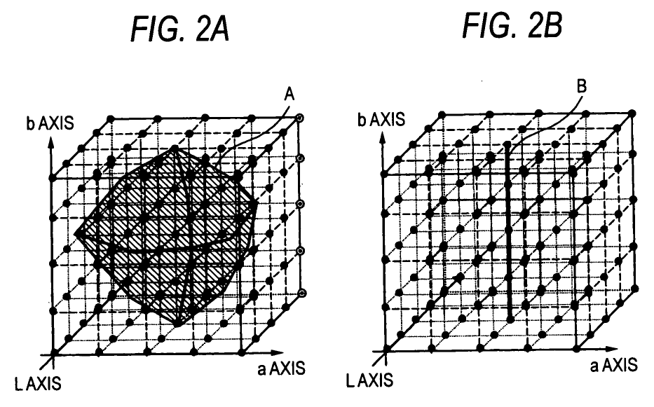

Here, the signal holding area in the first CLUT 3 will be described in detail. FIGS. 2A and 2B are explanatory views showing an example of the signal holding area in the CLUT.

In general, in the first CLUT 3, signal values of a color space at the output side after conversion of signal values at respective lattice points of a space obtained by dividing a color space at the input side are held at addresses corresponding to the respective lattice points. Accordingly, in the case where the signal value of the input image signal is one concerning the achromatic color, in order to output the signal value of only K as the signal value of the output image signal corresponding to the signal value of the input image signal, for example, as shown in FIG. 2B, it is conceivable that signal values of only K are held in an address area (see B in the drawing) corresponding to a gray axis in the L*a*b* color space, that is, an axis of a*=b*=0. However, in that case, when a signal value other than those at the lattice points is obtained by the interpolation, there can occur such a case that the interpolation is performed based on a signal value on the gray axis and a signal value on the adjacent lattice, that is, the signal value of only K and the signal value of YMC or YMCK. Accordingly, there is a fear that the reproduction of color becomes unnatural as to the signal value obtained by the interpolation.

On the other hand, in the first CLUT 3, there can exist the area on the coordinate axis which the signal value of the input image signal can not take. For example, when the input image signal is converted from the RGB color space to the L*a*b color space, the area (color reproduction area) on the coordinate axis which the signal value of the input image signal can take comes to have a complicated three-dimensional shape (see A in the drawing) as shown in FIG. 2A. The inside of the solid shown in the drawing is the area in which color reproduction can be performed, and its outside is an area in which color can not be reproduced, that is, the area which the signal value of the input image signal can not take.

From these, in the first CLUT 3, the holding area is secured in the area which the signal value of the input image signal can not take, and the specific color signal value is held in the holding area. Specifically, for example, when the first CLUT 3 corresponds to 256 gradations, in the case where the range of a* and b* is “−128” to “128”, it is conceivable that as indicated by double circles in FIG. 2A, an area on the axis of a*=b*=128 is secured as the holding area. However, the holding area is not limited to this, and as long as the area is one which the signal value of the input image signal can not take, it may be suitably set. Besides, according to the circumstances of the system in which the image processing apparatus is mounted, it is conceivable that in order to secure the holding area, in addition to the address area for the L*a*b* color space, the address area for the specific color signal value is added. That is, the first CLUT 3 may be one in which the address area for the specific color signal value is added to the outside of the address area for the predetermined color space.

In the area A on the coordinate axis which the signal value of the input image signal can take, the signal value of the output image signal corresponding to the signal value of the input image signal is correlated with the position on the coordinate axis in the predetermined color space (for example, the L*a*b* color space) and is held. Specifically, similarly to the related art, signal values of the color space (for example, respective colors of YMC or YMCK) at the output side after conversion at the respective lattice points of the space obtained by dividing the color space at the input side are held at the addresses corresponding to the respective lattice points. Incidentally, the color space at the input side may be an arbitrary color space such as an RGB color space, an L*a*b* uniform color space or an L*C*H° color space.

On the other hand, in the holding area secured in the area which the signal value of the input image signal can not take, signal values made of values not used as the signal value (signal value of the color space at the output side) of the output image signal are held as the specific color signal values. As the specific color signal value as stated above, for example, one including a value (lightness value, etc.) indicating the lightness in the input image signal can be mentioned. When the value indicating the lightness as stated above is used as the specific color signal value, as the signal value of the output image signal, for example, like Y=M=C=255, the value not used as the signal value of the color space at the output side is used, and the signal value on the gray axis can be expressed accurately and with less data amount. However, as long as the specific color signal value can be distinguished from the signal value of the output image signal, it is not limited to this.

In FIG. 1, the address creation part 4 creates an address of the first CLUT 3 according to the signal value of the color space at the input side. By the creation of the address in the address creation part 4, the first CLUT 3 outputs the signal value of the color space at the output side held at the created address. The address creation part 4 may create addresses corresponding to plural lattice points used for the interpolation calculation in the interpolation calculation part 5.

Further, as a result of a judgment as to whether or not the signal is one concerning the achromatic color in the color space signal conversion part 2, when the input image signal as the object of the color conversion is the one concerning the achromatic color, the address creation part 4 performs address conversion on the input image signal so that the specific color signal value in the holding area of the first CLUT 3 is outputted from the first CLUT 3.

The interpolation calculation part 5 performs the interpolation calculation on the signal value of the output image signal other than the specific color signal value outputted from the first CLUT 3 on the basis of the signal value thereof, and obtains the signal value concerning the coordinate point not corresponding to the lattice point. In the first CLUT 3, a reduction in storage capacity is enabled by including this interpolation calculation part 5. With respect to a method of the interpolation calculation, since the well-known art may be used, its description will be omitted here.

With respect to the specific color signal value outputted from the first CLUT 3 and after the interpolation calculation in the interpolation calculation part 5, the achromatic color conversion part 6 performs the achromatic color conversion processing for outputting the specific color signal value as the signal value of the color space at the output side, and obtains the signal value of the output image signal from the specific color signal value. For that purpose, the achromatic color conversion part 6 includes plural second CLUTs 6a and an interpolation calculation part 6b.

The second CLUTs 6a hold corresponding relations between the specific color signal values and the signal values of the output image signals. For details, with respect to the holding area in the first CLUT 3, the signal values of the color space at the output side after the conversion at the respective lattice points are held at addresses corresponding to the respective lattice points. However, the achromatic color conversion part 6 includes the plural second CLUTs 6a, that is, at least two second CLUTs 6a. From this, it is assumed that one of the second CLUTs 6a holds a signal value of, for example, each color of YMC or YMCK as the signal value of the output image signal corresponding to the specific color signal value (value indicating the lightness in the input image signal), and the other holds a signal value of only K in the color space as the signal value of the output image signal corresponding to the specific color signal value. Incidentally, since any-one of the second CLUTs 6a has only to handle a part corresponding to the holding area in the first CLUT 3, not the whole color space, its storage capacity may be very small as compared with the first CLUT 3.

With respect to the signal value of the output image signal corresponding to the specific color signal value outputted from the second CLUT 6a, the interpolation calculation part 6b performs the interpolation calculation based on the signal value, and obtains a signal value concerning a coordinate point not corresponding to the lattice point. Incidentally, the interpolation calculation may be performed similarly to the interpolation calculation part 5. In the case where the second CLUTs 6a hold the output image signal values corresponding to all input data, the interpolation calculation part 6b is unnecessary.

The object judgment part 7 makes an object judgment as to the specific color signal value. For details, with respect to the specific color signal value as the object of the achromatic color conversion processing in the achromatic color conversion part 6, the object judgment is made as to whether the specific color signal value is for outputting graphics (for example, text and figure) or for outputting a natural picture (for example, photograph). In the object judgment part 7, the result of the object judgment is notified to the achromatic color conversion part 6. By this notification, in the achromatic color conversion part 6, it becomes possible to select one of the plural second CLUTs 6a.

Here, the object judgment will be described in brief. Generally, there is a case where different objects such as graphics (for example, a text or a figure) and a natural picture (for example, a photograph) are mixed in a color image expressed by an input image signal. In the respective objects, their respective optimum achromatic color conversion processings are not necessarily the same. For example, in the case of the graphics, an achromatic color conversion processing for reproduction with only the K color is suitable, and in the case of the natural picture, an achromatic color conversion processing for reproduction with the K color and colors other than the K color is suitable. This is because with respect to the achromatic color, when the whole thereof is reproduced by only the K color, the reproduction of the photograph or the like makes a blurred impression, and in the case where all colors are reproduced with the K color and colors other than the K color, there is a possibility that a color shift occurs with respect to a black character or black graphics. Further, for example, in the case where billing is performed for the print output of an image, since the case where only the K color is used is different in billing fee from the case where the K color and the colors other than the K color are used, that is, the case of full color, it is necessary to clearly distinguish the respective cases.

Thus, when the color conversion processing of the input image signal is performed, it is also conceivable to make the object judgment on the input image signal. With respect to the object judgment, various methods are known. However, according to the circumstances of the system in which the image processing apparatus for performing the color conversion processing is mounted, there can occur such a case that the object judgment can not be made at the input time of the input image signal to the image processing apparatus, and it becomes possible to make the object judgment first at the stage after the start of the color conversion processing in the image processing apparatus.

From this, the object judgment part 7 makes the object judgment concerning the specific color signal value so that even in the case where the object judgment of the input image signal can not be made at the time of the start of the color conversion processing according to the state of the system, the object judgment is enabled and the achromatic color conversion processing optimum for the respective objects can be performed. Incidentally, since a well-known technique may be used as a method of the object judgment, its description is omitted here.

The output part 8 is for outputting the output image signal. As the output image signal, for example, a color image signal of the YMC color space or YMCK color space to be printed by a printer or the like can be mentioned.

The UI part is for performing various settings for the respective parts 1 to 8 by the operation of a user.

Incidentally, in the structural example shown in FIG. 1, although the example in which only one first CLUT 3 is provided is cited as an example, in the first CLUT 3, plural CLUTs may be provided in which the corresponding relations between the signal value of the input image signal and the signal value of the output image signal are different from each other. When the plural first CLUTs 3 are provided, for example, it becomes possible to perform color conversion suitable for an image using bright color, to perform color conversion suitable for an image in which colors are mixed, or to perform color conversion suitable for a case where it is necessary to accurately coordinate colors. However, in that case, it is assumed that either one of the plural first CLUTs 3 can be selected. With respect to the selection, it is conceivable to enable the UI part to perform the selection. The selection result can be recognized by, for example, an identification signal called “Intent”. That is, in the case where the plural first CLUTs 3 are provided, the identification signal indicating the selection result of the respective first CLUTs 3 is made to be included in the specific color signal value, and the selection result is made to be capable of being recognized by the achromatic color conversion part 6. When such is performed, it also becomes possible to change the second CLUT 6a by the identification signal, and it becomes possible to further optimize the achromatic color conversion processing.

These parts 1 to 8 are included in, for example, an image output apparatus, a server apparatus or a driver apparatus, and it is conceivable that they are respectively realized by executing a predetermined program by a computer constructed of the combination of a CPU (Central Processing Unit), a ROM (Read Only Memory), a RAM (Random Access Memory) and the like. That is, the image processing apparatus of the structure as described above can also be realized by the image processing program for causing the computer to function as the image processing apparatus.

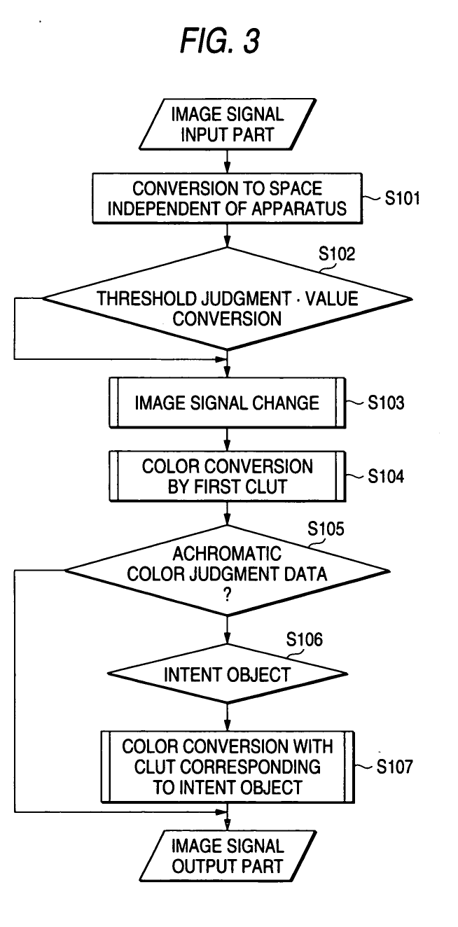

Next, in the image processing apparatus constructed as described above, the processing procedure in the case where the input image signal is converted to the output image signal, that is, the image processing method will be described. FIG. 3 is a flowchart showing an example of the processing procedure in the image processing method of this invention.

In the case where the input image signal is converted to the output image signal, with respect to the input image signal inputted to the input part 1, first, the color space signal conversion part 2 performs a color space conversion processing to a color space which is independent on an apparatus (step 101, a step is hereinafter abbreviated to “S”). With respect to the input image signal after the color space conversion processing, the color space signal conversion part 2 compares it with a predetermined threshold and judges whether or not the signal value of the input image signal is one concerning the achromatic color, and the address creation part 4 creates the address of the first CLUT 3 according to the signal value of the color space at the input side (S102 to S103). At this time, with respect to the input image signal judged to be one concerning the achromatic color, the address conversion on the input image signal is performed so that a specific color signal value in the holding area is outputted from the first CLUT 3.

In this way, the address is created in the address creation part 4, and when the created address is inputted, the first CLUT 3 outputs the signal value, which is held at the address, of the color space at the output side, so that the color conversion on the input image signal is performed (S104). At this time, when the signal value from the first CLUT 3 is not one concerning the achromatic color (S105), since it is the signal value of each color of YMC or YMCK, it is subjected to the interpolation calculation by the interpolation calculation part 5 as the need arises, and then is outputted from the output part 8 as the signal value of the output image signal after the color conversion.

However, when the signal value from the first CLUT 3 is one concerning the achromatic color (S105), the signal value is the specific color signal value. Accordingly, this is not outputted from the output part 8 as it is, but the achromatic color conversion part 6 performs a processing as follow. That is, the achromatic color conversion part 6 changes the second CLUT 6a to be applied to the specific color signal value on the basis of at least one of the result of the object judgment by the object judgment part 7 as to the specific color signal value and the identification signal (intent) included in the specific color signal value (S106 to S107). Specifically, for example, when the specific color signal value is for outputting graphics, the achromatic color conversion part 6 selects the second CLUT 6a for changing a value indicating the lightness in the specific color signal value to a signal value of only the K axis. Besides, for example, when the specific color signal value is for outputting a natural picture, the achromatic color conversion part 6 selects the second CLUT 6a for converting the value indicating the lightness in the specific color signal value to signal values of the respective colors of YMC or YMCK. These signal values are subjected to the interpolation calculation by the interpolation calculation part 6b as the need arises, and then are outputted from the output part 8 as the signal values of the output image signal after the color conversion.

As described above, according to the color image processing apparatus and the color image processing method (including the color image processing program for realizing these) described in the embodiment, the holding area is secured in the first CLUT 3 and in the area on the coordinate axis which the signal value of the input image signal can not take and holds the specific color signal value, and further, when the signal value of the input image signal is one concerning the achromatic color, the address creation part 4 performs the address conversion on the input image signal so that the specific color signal value is outputted as the signal value of the output image signal from the first CLUT 3. Thus, at the image formation based on the output image signal, with respect to the achromatic color, it becomes possible to perform the image formation using only the toner of K color through the processing in the achromatic color conversion part 6. Accordingly, even in the case where after the color space conversion processing on the input image signal whose signal value is one concerning the achromatic color, the output image signal after the processing is outputted as the color image by the electrophotographic system, it is possible to reduce various disadvantages which are caused by the increase of the toner amount, for example, the occurrence of a blur or the like in the electrophotographic system, and the picture quality can be improved.

Further, since the specific color signal value is not held in the area (see the area A in FIG. 2A) on the coordinate which the signal value of the input image signal can take, for example, even in the case where the interpolation calculation part 5 obtains a signal value by the interpolation calculation from the held content in the first CLUT 3, it is not necessary to perform the interpolation using the specific color signal value, and it is possible to prevent the color reproduction of the signal value from becoming unnatural, and therefore, also in this point, the picture quality can be improved.

That is, in both the case where the signal value of the input image signal indicates the achromatic color and the case where it indicates a color near the achromatic color, it becomes possible to output the signal value of the output image signal which is excellently reproduced, and as a result, it becomes possible to realize the output of the high quality color image.

Besides, in this embodiment, since the object judgment part 7 makes the object judgment as to the specific color signal value, even in the case where the achromatic color conversion processing (so-called gray processing) can not be performed according to the system condition, it becomes possible to optimize the gray processing for each object, and it becomes possible to realize the optimum color reproduction for the photograph, black character or black graphics.

Further, since the holding area is secured in the first CLUT 3 and the specific color signal value is held, even in the case where the signal value to be subjected to the gray processing is not known before the signal input to the first CLUT 3, the normal color conversion can be performed, and an influence is not given in the result of the color conversion, and therefore, also in this point, it becomes possible to realize the improvement in the picture quality of the output image.

Besides, when the gray processing is performed using the CLUT, the speed-up of the processing speed can be realized.

As described in this embodiment, in the case where the plural first CLUTs 3 are provided, it becomes possible to perform the processing corresponding to the plural intents, and it becomes possible to further optimize the color conversion processing. That is, since the plural intents which can be changed are used as the input value to the second CLUT 6a, even in the case where the gray processing to be performed varies for the respective intents, it becomes possible to deal with this, and this embodiment becomes very effective in optimization of the color conversion processing.

Besides, although the description has been given to the example suitably used for the case where the specific color is the achromatic color and the color conversion processing concerning the achromatic color is performed, this invention is not limited to this. Even if the specific color is one other than the achromatic color, the invention can be applied quite similarly.

As the specific color other than the achromatic color, for example, a spot color such as a corporate color can be mentioned. The corporate color is the color very important to the formation of the bland image of a company. The spot color typified by the corporate color as stated above is severe in the demand for color. When the respective colors of YMCK are changed and adjusted in order to cope with such demand, there can occur such a case that a color near the spot color and other than the spot color is not reproduced to be a desirable color. Further, when an address area in the vicinity of the designated spot color is partially color changed, there can occur such a case that the continuity of color is lost.

On the other hand, when the previously designated spot color is set as the specific color signal value by the application of this invention, the address conversion of the judged spot color is performed, so that even in the case where a color other than the spot color is made to be subjected to different color reproduction, it becomes possible to perform the conversion to the output image signal without receiving the influence of interpolation. Incidentally, also in the case where the spot color is outputted as the specific color signal value by first CLUT 3, the object judgment is made and the output image signal value for performing the color conversion of the spot color has only to be set by the second CLUT 6a for each object. Specifically, since the spot color such as the corporate color is often used in graphics, it is conceivable that the color conversion of the spot color is performed only in the case where the object is graphics, and in the case where the object is a natural picture, the color conversion for the natural picture is performed. Besides, the output image signal value can be directly outputted as the specific color signal value of the first CLUT 3, and in this case, the specific color conversion is not performed.

As described above, according to an embodiment of the present invention, the image processing apparatus for color converting an input image signal to an output image signal includes a multidimensional look-up table that correlates a signal value of the output image signal corresponding to a signal value of the input image signal with a position on a coordinate axis in a predetermined color space and holds it, secures a holding area for holding a specific color signal value in an area on the coordinate axis. The area is not taken by the signal value of the input image signal. Also, the apparatus has a judgment unit which judges whether a signal value of the input image signal is a specific color or not. When the input image signal is the specific color, address conversion is performed on the input image signal, and the specific color signal value in the holding area is acquired based on the multidimensional look-up table.

According to another embodiment of the present invention, the image processing method for color converting an input image signal to an output image signal has, correlating a signal value of the output image signal corresponding to a signal value of the input image signal with a position on a coordinate axis in a predetermined color space and holding it in a multidimensional look-up table, securing in the multidimensional look-up table a holding area in an area on the coordinate axis. The area is not taken by the signal value of the input image signal, and also holding a specific color signal value, judging whether or not, a signal value of the input image signal is a specific color, performing, when the input image signal is the specific color, address conversion on the input image signal, and acquiring the specific color signal value in the holding area as a signal value of the output image signal based on the multidimensional look-up table.

According to another embodiment of the present invention, a storage medium readable by a computer stores an image processing program of instructions executable by the computer to perform a function for color converting an input image signal to an output image signal, the function has correlating a signal value of the output image signal corresponding to a signal value of the input image signal with a position on a coordinate axis in a predetermined color space and holding it in a multidimensional look-up table, securing in the multidimensional look-up table a holding area in an area on the coordinate axis which the area is not taken by the signal value of the input image signal and holding a specific color signal value, judging whether or not, the signal value of the input image signal is a specific color, performing, when the input image signal is the specific color, address conversion on the input image signal, and acquiring the specific color signal value in the holding area based on the multidimensional look-up table.

According to the image processing apparatus, the image processing method, and the image processing program, since the multidimensional look-up table correlates the signal value of the output image signal corresponding to the signal value of the input image signal with the position on the coordinate axis in the predetermined color space (for example, CIE-L*a*b* color space) and holds it, it is possible to realize that when the signal value of the input image signal is inputted to the multidimensional look-up table, the signal value of the output image signal corresponding thereto is outputted from the multidimensional look-up table. At this time, the multidimensional look-up table secures the holding area in the area on the coordinate axis which the area is not taken by the signal value of the input image signal and holds the specific color signal value (for example, the signal value of only the lightness concerning the achromatic color), and when the signal value of the input image signal is the specific color (in addition to one concerning the specific color, for example, one with a color value in which a distance from a specific color axis is a predetermined threshold or less; incidentally, an achromatic color or the like can be mentioned as the specific color), the address conversion is performed on the input image signal, so that the specific color signal is acquired based on the multidimensional look-up table as the signal value of the output image signal. Thus, at the image formation on the basis of the output image signal, with respect to the achromatic color, it becomes possible to perform the image formation using only the toner of K color while corresponding to the specific color signal value. Further, since the specific color signal value is not held in an area on the coordinate axis which the signal value of the input image signal can take, for example, even in the case where a signal value is obtained by interpolation from the held content in the multidimensional look-up table, it is not necessary to perform the interpolation using the specific color signal value, and it becomes possible to prevent the color reproduction of the signal value from becoming unnatural.

The foregoing description of the embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

The entire disclosure of Japanese Patent Application No. 2003-429667 filed on Dec. 25, 2003 including specification, claims, drawings and abstract is incorporated herein by reference in its entirety.

1. An image processing apparatus for color converting an input image signal to an output image signal, comprising:
a multidimensional look-up table that correlates a signal value of the output image signal corresponding to a signal value of the input image signal with a position on a coordinate axis in a predetermined color space and holds it, secures a holding area for holding a specific color signal value in an area on the coordinate axis, the area is not taken by the signal value of the input image signal; and
a judgment unit that judges whether the signal value of the input image signal is a specific color or not, wherein when the input image signal is the specific color, address conversion is performed on the input image signal, and the specific color signal value in the holding area is acquired based on the multidimensional look-up table.

2. An image processing apparatus according to claim 1, wherein the specific color is an achromatic color.

3. An image processing apparatus according to claim 1, wherein the specific color signal value includes a value which is not used as the signal value of the output image signal corresponding to the signal value of the input image signal.

4. An image processing apparatus according to claim 1, further comprising:
a specific color conversion unit that, performs specific color conversion on the specific color signal value to obtain the signal value of the output image signal from the specific color signal value when the specific color signal value is acquired based on the multidimensional look-up table.

5. An image processing apparatus according to claim 4, further comprising:
an object judgment unit that judges an object for the specific color signal value; and
a second look-up table that holds corresponding relation between the specific color signal value and the signal value of the output image signal,
wherein the specific color conversion unit changes the look-up table to be used when the specific color conversion is performed, based on the object.

6. An image processing apparatus according to claim 2, wherein the specific color signal value includes a value indicating lightness in the input image signal.

7. An image processing apparatus according to claim 1, further comprising:
a plurality of multidimensional look-up tables, the multidimensional look-up table is selected, and wherein the specific color signal value includes an identification signal of the selected multidimensional look-up table.

8. An image processing apparatus according to claim 7, wherein as an input value to the second lookup table, a specific color signal value including both the value indicating the lightness and the identification signal is used, and
the input value includes a plurality of changeable identification signals.

9. An image processing apparatus according to claim 7, wherein the specific color conversion unit changes the second lookup table by the identification signal.

10. An image processing apparatus according to claim 1, wherein the multidimensional look-up table includes an address area for the predetermined color space and an address area for the specific color signal value.

11. An image processing apparatus according to claim 1, further comprising:
a user interface unit that selects whether or not color conversion using the specific color signal value is performed.

12. An image processing method for color converting an input image signal to an output image signal, comprising:
correlating a signal value of the output image signal corresponding to a signal value of the input image signal with a position on a coordinate axis in a predetermined color space and holding it in a multidimensional look-up table;
securing a holding area for holding a specific color signal value in an area on the coordinate axis in the multidimensional look-up table, the area is not taken by the signal value of the input image signal;
judging whether a signal value of the input image signal a specific color or not;
wherein when the input image signal is the specific color, address conversion on the input image signal is performed to acquire the specific color signal value in the holding area as the signal value of the output image signal based on the multidimensional look-up table.

13. An image processing method according to claim 12, wherein the specific color is an achromatic color.

14. An image processing method according to claim 12, wherein the specific color signal value includes a value which is not used as the signal value of the output image signal corresponding to the signal value of the input image signal.

15. An image processing method according to claim 12, wherein specific color conversion is performed on the specific color signal value to obtain the signal value of the output image signal from the specific color signal value, when the specific color signal value is acquired based on the multidimensional look-up table.

16. An image processing method according to claim 15, further comprising:
providing a second look-up table that holds corresponding relation between the specific color signal value and the signal value of the output image signal;
judging an object for the specific color signal value; and
changing the lookup table to be used when the specific color conversion is performed based on the object.

17. An image processing method according to claim 13, wherein the specific color signal value includes a value indicating lightness in the input image signal.

18. An image processing method according to claim 12, wherein a plurality of multidimensional look-up tables are provided, the multidimensional look-up table is selected, and the specific color signal value includes an identification signal of the selected multidimensional look-up table.

19. An image processing method according to claim 18, wherein a specific color signal value including both the value indicating the lightness and the identification signal is used as an input value to the second lookup table, and
the input value includes a plurality of changeable identification signals.

20. An image processing method according to claim 18, wherein when specific color conversion is performed, the second lookup table is changed by the identification signal.

21. An image processing method according to claim 12, wherein the multidimensional look-up table includes an address area for the predetermined color space and an address area for the specific color signal value.

22. An image processing method according to claim 12, wherein a user interface unit is used to select whether or not color conversion using the specific color signal value is performed.

23. A storage medium readable by a computer storing an image processing program of instructions executable by the computer to perform a function for color converting an input image signal to an output image signal, the function comprising:
correlating a signal value of the output image signal corresponding to a signal value of the input image signal with a position on a coordinate axis in a predetermined color space and holding it in a multidimensional look-up table;
securing a holding area for holding a specific color signal value in an area on the coordinate axis in the multidimensional look-up table, the area is not taken by the signal value of the input image signal;
judging whether a signal value of the input image signal is a specific color or not;
performing address conversion on the input image signal when the input image signal is the specific color; and
acquiring the specific color signal value in the holding area based on the multidimensional look-up table.

24. A storage medium according to claim 23, wherein the specific color is an achromatic color.

25. A storage medium according to claim 23, wherein the specific color signal value includes a value which is not used as the signal value of the output image signal corresponding to the signal value of the input image signal.

26. A storage medium according to claim 23, wherein specific color conversion is performed on the specific color signal value to obtain the signal value of the output image signal from the specific color signal value, when the specific color signal value is acquired based on the multidimensional look-up table.

27. A storage medium according to claim 26 further comprising:
providing a second look-up table that holds corresponding relation between the specific color signal value and the signal value of the output image signal;
judging an object for the specific color signal value; and
changing the lookup table to be used when the specific color conversion is performed based on the object.

28. A storage medium according to claim 24, wherein the specific color signal value includes a value indicating lightness in the input image signal.

29. A storage medium according to claim 23, wherein a plurality of multidimensional look-up tables are provided, the multidimensional look-up tables is selected, and the specific color signal value includes an identification signal of the selected multidimensional look-up table.

30. A storage medium according to claim 29, wherein a specific color signal value including both the value indicating the lightness and the identification signal is used as an input value to the second lookup table, and
the input value includes a plurality of changeable identification signals.

31. A storage medium according to claim 29, wherein when specific color conversion is performed, the second lookup table is changed by the identification signal.

32. A storage medium according to claim 23, wherein the multidimensional look-up table includes an address area for the predetermined color space and an address area for the specific color signal value.

33. A storage medium according to claim 23, wherein a user interface unit is used to select whether or not color conversion using the specific color signal value is performed.
